(19) United States
(12) Patent Application Publication
(10) Pub. No.: US 2011/0068880 A1
(43) Pub. Date: Mar. 24, 2011

(54) MICROMECHANICAL NETWORK

(76) Inventor: GAVIN HO, FOSTER CITY, CA (US)

(21) Appl. No.: 12/885,330

(22) Filed: Sep. 17, 2010

Related U.S. Application Data
(60) Provisional application No. 61/276,960, filed on Sep. 18, 2009.

(30) Foreign Application Priority Data
Sep. 17, 2010 (US) PCT/US10/49389

(51) Int. Cl. H03H 9/56

(52) U.S. Cl. 333/188

(57) ABSTRACT

An electrical network and method of manufacturing thereof. A substrate containing an acoustic resonator enclosed in a cavity. An apparatus includes a substrate with a cavity and a network. The network has a resonator formed on a substrate, the resonator being enclosed within the resonator cavity. A capacitive device is formed on the same substrate and connected in series with the resonator. The capacitive device has a conductive film and a solid-dielectric film. The conductive film has high absorption to a select laser wavelength. The network has at least two open-ended electrical contacts on the substrate for an off-substrate electrical connection.

### RELATED APPLICATIONS

This application claims priority to U.S. Provisional Patent Application No. 61/276,960, entitled “Micromechanical Resonator and Series Capacitor,” filed on Sep. 18, 2009.

### BACKGROUND

1. Field of the Invention

Aspects of the present invention relate in general to electronical resonators. Aspects include an analog electrical network formed on a substrate containing a high quality factor acoustic resonator enclosed in a cavity. Additional aspects include a low-cost method of manufacturing a fixed-frequency oscillator.

2. Description of the Related Art

Frequency References

An electrical network comprising a resonator (e.g., electrical, electromechanical, and electromagnetic resonators) can be used as a frequency reference for electrical systems. Frequency references determine the oscillation frequency in an oscillator loop by providing a stable frequency at which the phase shift in the loop is zero (or an integer multiple of 2π). Considering an oscillator to have three parts; the gain stage, the feedback network, and auxiliary components; the oscillation frequency is largely determined by the phase shift in the feedback network.

Electromechanical or “acoustic” resonators are a popular choice for the feedback network because of their phase characteristics. Acoustic resonators can provide excellent frequency stability because they can attain excellent quality factor Q. A high Q provides a high gradient of phase over frequency (i.e., a sharp phase transition). Acoustic resonators are enclosed in a cavity for long-term stability and performance.

The zero-phase frequency of the oscillator is closely dependent on the resonant frequency of the network. (A resonant frequency is a frequency at which the phase shift is zero and the impedance is low. At an anti-resonant frequency, the phase shift is zero and the impedance is high.) The resonant frequency of the network is dependent on the resonant frequency of the constituent resonator.

In the activity of manufacturing the constituent resonator, variations will be observed in the resonant frequency. The extent of these variations is one culprit of high manufacturing cost. Large variations are not resolvable and reduce the manufacturing yield. Moderate variations must be reduced to acceptable tolerances through additional processing activities. Such activities are essential and costly.

The manufacturing cost of a frequency reference and/or resonator is also dependent on the cost of the packaging and the cost of the required interface circuitry.

Fixed-Frequency Oscillators

Fixed-frequency oscillators and voltage-controlled oscillators (VCO) utilize frequency references. The primary distinction between the two categories is referencing. Whereas fixed-frequency oscillators are self-referenced (i.e., there are no frequency-control inputs into the oscillator), VCO are dynamically tuned in operation by an input control. Since fixed-frequency oscillators utilize a self-referenced feedback network, the feedback network must provide the desired resonant frequency. Prior art in the method of manufacturing acoustic resonators for accurate fixed-frequency oscillators utilize the following sequence: (1) partial processing of the resonator, (2) trim the resonator, and (3) enclose the resonator.

Quartz Crystal Units

A quartz crystal unit, the most common type of frequency reference, consists of a quartz resonator which is formed out of a quartz substrate. In some designs, the quartz substrate is thinned to a certain dimension to provide the desired resonator frequency. In other designs, the quartz substrate is patterned and etched to create the geometry of the resonators. Metallic films are deposited and patterned on the substrate. The substrate is then singulated into individual resonators. The resonators are then mounted onto a holder. The holder is most commonly the base of a metal package or a ceramic package. At this step, each resonator is electrically tested and trimmed by material addition or removal. The metal or ceramic package is then enclosed to provide a clean cavity in which the resonator can operate. The metal or ceramic packages can then be attached to a larger substrate, such as a printed circuit board, to interface with other electrical components. An alternative implementation is the placement of a semiconductor integrated circuit (IC), also known as a “transistor network,” inside a ceramic package containing the quartz resonator, wherein the IC is connected to the quartz resonator through wire-bonds, as in the case of discrete crystal oscillators (XO).

A number of inefficiencies exist in the manufacturing and distribution of quartz crystal units, also known as quartz crystals. First, the process of reducing variations in quartz crystals is done after singulation and mounting. Next, because quartz substrates are small relative to semiconductor and glass substrates, fewer devices can be placed on a quartz substrate and be processed in parallel. Third, the cost and processing of metal and ceramic packages is high. Finally, long lead times and high inventories are associated with quartz crystals. Because the quartz crystal must be specific to the network (i.e., specific to the load capacitances of the network), the resonator trimming and subsequent processing are custom to order. Due to the long custom-order processing cycle, excessive inventories for quartz crystals of various frequencies and various load capacitances are kept in the distribution chain to maintain reasonable time to delivery.

Quartz crystal units are being reduced in size. Quartz crystals are produced in a variety of package sizes. HC-49 metal packages and its variations are suitable for non-space-constrained applications. Applications requiring reduced z-height and/or reduced footprint (i.e., lateral dimensions) require expensive ceramic packages. As of 2010, quartz crystal units in 3.2 mm by 2.5 mm and 2.5 mm by 2.0 mm ceramic packages are common. Some crystal units are produced in ceramic packages with as low as 0.4 mm z-height. As of 2010, quartz crystals in 1.2 mm by 1.0 mm and 1.0 mm by 0.8 mm in-plane dimensions have appeared in product roadmaps. However, as the size is reduced, packaging is increasingly more challenging and thus more expensive.

Ceramic Resonators

Ceramic resonators are lower-cost alternatives to quartz crystals in less-stringent applications. Similar to quartz crystals, ceramic resonators are formed out of a piezoelectric substrate. The resonator substrate is enclosed in a stack of additional ceramic alumina substrates; the substrates have frames and covers that subsequently form a cavity. A minimum of five substrates are required. At the least one substrate is required for each of the following parts: a top cover, a top frame, the resonator, a bottom frame, and a bottom cover. The stack of ceramic substrates is constructed by low-temperature co-fired ceramic (LTCC) or high-temperature co-fired ceramic (HTCC) technology, similar to the method of producing ceramic packages for microelectronic components and quartz crystals. Ceramic resonators have limited use in electronics as their performance is inferior to quartz crystals. In particular, the frequency accuracy of ceramic resonators (as-fabricated, over temperature, and aging) are not suitable for most applications.

Film Bulk Acoustic Wave Resonators

Film bulk acoustic wave (BAW) resonators are formed by disposing a piezoelectric film on a substrate, such as silicon, sapphire, other semiconductor materials and glass. The acoustic mode is a thickness-extensional mode and is largely in the direction normal to the piezoelectric film. Electrodes formed from conductive films are also disposed on the substrate. Film BAW resonators can be classified into two categories: suspended and solidly-mounted. In suspended resonators, the thickness of the suspended structure (i.e. the piezoelectric film, the conductive films, and any other films in the device) determines the resonant frequency. Solidly-mounted resonators, which are disposed on a Bragg reflector, have resonant frequencies that are similarly dependent on the thickness of the piezoelectric stack.

The standard method of trimming the resonant frequency is by material addition or material removal using an ion beam or etching. The trim process is performed mid-way through the manufacturing process while the resonator can be exposed to the incident ions and/or reactants. Next, the cavity can be formed by bonding an additional substrate on the first substrate to protect the resonator. The resonant frequency of film BAW resonators is typically above 500 MHz because disposing piezoelectric films thicker than several micrometers is rarely feasible. Because of the high resonant frequency, the inductance of an electrical connection to the resonator impacts its operation. For this reason, these film BAW resonators are either manufactured on the same substrate as their interface IC, or they are connected to a an interface IC formed on a second substrate through short wire bonds.

SAW Resonators

SAW resonators are formed by depositing a conductive film on a piezoelectric material. The piezoelectric material is a bulk material or a deposited film. Interdigitated electrodes are patterned out of the conductive film. The variation in the thickness and line width of the interdigitated electrodes and variation in the piezoelectric material lead to variations in the resonant frequency of the SAW resonator. Trimming by removing material from the conductive interdigitated electrodes and/or the piezoelectric material is performed similar to film BAW resonator trimming. The SAW resonator must be exposed to incident ions and/or reactants. Prior art SAW resonators have poor temperature stability. SAW resonator almost always have resonant frequencies higher than several hundred MHz. High-frequency oscillators have high power dissipation. For these reasons, SAW resonators are unsuitable as replacements for low-power fixed-frequency oscillators.

Micromechanical Resonators

Micromechanical resonators are acoustic resonators formed on a substrate using manufacturing processes similar to those used in microelectronic (e.g. semiconductor) manufacturing. The resonators are flexural-mode, lateral-extensional mode, laterial-shear-mode, torsional-mode, thickness-extensional-mode, thickness-shear-mode, alternative-mode, and combinations thereof. Thickness-mode film BAW resonators, SAW resonators, and quartz resonators are also micromechanical resonators. Micromechanical resonators require a cavity for operation, as in the other forms of acoustic resonators. Micromechanical resonators with operating resonant frequencies below 10 kHz and above 1 GHz have been demonstrated in laboratory environments. Frequencies lower than 500 MHz rarely have thickness-mode resonance. The resonance modes below 500 MHz include flexural modes, lateral extensional modes, lateral shear modes, torsional modes, other modes, or a combination thereof. (A lateral mode is predominantly in the plane of the disposed films.) As the electrical characteristics of prior art micromechanical resonators are vastly dissimilar to quartz crystals, prior art micromechanical resonators cannot be used directly in place of quartz crystals. For this reason, custom integrated circuits are required to electrically interface to micromechanical resonators. Prior art micromechanical resonators have inaccurate resonant frequencies and undesirable temperature characteristics. As such, complex power-hungry correction technology such as fractional-N phase-locked loops is utilized. As this active correction is done specific to each resonator, the resonator must be electrically connected to the interface circuit before the programming (i.e. digital trimming) is performed. To summarize, integrated circuits and micromechanical resonators share a common package to accommodate their electrical interface and correction technology.

Resonators and Series Capacitive Devices

Modulating the resonant frequency of a feedback network can be performed by varying a constituent capacitance. Feedback networks such as quartz crystals and film BAW resonators utilize tunable capacitors for VCO applications. Placing a capacitance in series with an acoustic resonator is termed “series capacitance loading”. The series resonant frequency will shift as a result of changing the series capacitance. Since the effect of capacitive loading on quartz is small, capacitive loading cannot obviate quartz crystal trimming for frequency accuracy. Film BAW resonators and variable-capacitance devices such as varactor diodes, digitally-controlled capacitor arrays, and tunable capacitors formed on the same substrate are known to those skilled in the art for VCO applications. Film BAW resonator substrates for VCO application have IC on the substrate to interface to the resonator. In such implementations, the feedback network does not have an open-ended port or open-ended electrical contact on the substrate for off-substrate connection.

Integrated Circuits

Integrated circuit substrates having an acoustic resonator is prior art. However, disposing of additional films on an IC substrate is unattractive for many reasons including (1) the additive cost of processing the substrate, (2) the likely reduction in yield, (3) the limitation of low-temperature processing to minimize shifts in transistor performance.

Capacitive Devices on a Substrate

A variety of capacitive devices can be formed on a substrate. Capacitive devices are capacitors and devices that exhibit capacitive behavior under certain conditions. For example, quartz resonators, film BAW resonators, and micromechanical resonators exhibit capacitive behavior at frequencies spectrally-distal from their resonant frequency.

Bandpass Filters

Bandpass filter networks utilizing acoustic resonators are similar in appearance to oscillators. Bandpass filters are commonly implemented using ladder networks, especially in RF applications, wherein acoustic resonators are arranged in series-shunt combinations. Since a bandpass filter having only one resonator has poor out-of-band rejection, practical bandpass filter networks have more than one resonator. Constituent resonators in bandpass filter networks also require trimming for frequency accuracy. Direct modification of the constituent resonators such as material addition or removal is performed. Series capacitance loading reduces the achievable bandwidth and/or increases the insertion loss of a bandpass filter, so capacitance trimming for a filter is impractical. Therefore, utilizing a band-pass filter in a fixed-oscillator application, wherein a second resonator is used for capacitive-loading a network to modify the resonant frequency is not optimal and non-obvious.

Trimming of Feedback Networks

Trimming a network with an acoustic resonator is non-trivial for several reasons. (1) Trimming the constituent resonator before it is enclosed in a cavity is challenging and not accurate. Electrical characterization is required before trim. The characterization conditions should be the same as operating conditions for accurate trimming. However, replicating the operating conditions, such as a reduced-pressure and/or noble gas, in a characterization environment are costly and/or not possible. (2) The process of enclosing the resonator in a cavity also affects the characteristics of a trimmed resonator. (3) Although laser trimming has performed on a resonator enclosed in a ceramic package with a glass lid, there are some undesirable attributes. For example, the cost of a package with a glass lid is high. Laser trimming a resonator has been shown to negatively impact its performance. Therefore, the trimming process of a feedback network with an acoustic resonator can be improved.

### SUMMARY

An electrical network and method of manufacturing thereof. A substrate containing an acoustic resonator enclosed in a cavity. An apparatus includes a substrate with a cavity and a network. The network has a resonator formed on a substrate, the resonator being enclosed within the resonator cavity. A capacitive device is fanned on the same substrate and connected in series with the resonator. The capacitive device has a conductive film and a solid-dielectric film. The conductive film has high absorption to a select laser wavelength. The network has at least two open-ended electrical contacts on the substrate for an off-substrate electrical connection

A structure contains a high quality factor resonator enclosed in a cavity. An apparatus includes a substrate with a cavity and a network. The network has a resonator formed on a substrate, the resonator being enclosed within the resonator cavity. A capacitive device is formed on the same substrate and connected in series with the resonator. The the network has at least two open-ended electrical contacts on the substrate for an off-substrate electrical connection.

### BRIEF DESCRIPTION OF THE DRAWING

FIG. 1 depicts methods of manufacturing a structure containing a high quality factor resonator enclosed in a cavity in series with a capacitor.

FIG. 2 illustrates cross-sectional views of a substrate comprising a network that includes a resonator, a cavity, and a series capacitive device. Six embodiments of the arrangement of series capacitive device is illustrated in FIG. 2A through FIG. 2F.

FIG. 3 illustrates the process flow of initial substrate, intermediary substrate, and mother substrate, and singulating to obtain a final substrate. A process using three initial substrates is illustrated in FIG. 3A. A process using one initial substrate is illustrated in FIG. 3B.

FIG. 4 illustrates three exploded-assembly cross-sectional views of a deconstructed cavity in an intermediary substrate.

FIG. 5 illustrates two types of vertical interconnects (via) that may be formed in or on a substrate.

FIG. 6 illustrates cross-sectional views of a substrate comprising a network that includes a resonator and two series capacitive devices.

FIG. 7 illustrates a cross-sectional view of a substrate comprising a network that includes a resonator and a parallel combination of two capacitors connected in series to the resonator.

FIG. 8 illustrates cross-sectional views of a substrate comprising a network that includes a resonator, a series capacitive device, and a capacitive device in parallel to various branches of the network.

FIG. 9A illustrates a network comprising a resonator and series capacitor and two load capacitors shunted to a third port. FIG. 9B illustrates a cross-sectional view of a substrate comprising the network.

FIG. 10 illustrates cross-sectional views of a substrate comprising a network that includes more than one resonator.

FIG. 11A illustrates a cross-sectional view of a substrate comprising open-ended external electrical contacts to the ports of a network. FIG. 11B is a perspective view of a substrate with recessed electrical contacts. FIG. 11C to FIG. 11E are cross-sectional views of additional embodiments of a substrate comprising open-ended external electrical contacts

FIG. 12 illustrates cross-sectional views of a substrate comprising more than a network. FIG. 12A illustrates two networks. FIG. 12B illustrates a network and an additional device. FIG. 12C illustrates open-ended ports of a network and an additional device on the substrate. FIG. 12D illustrates network and additional device connected.

FIG. 13 illustrates cross-sectional views of a substrate comprising a network placed on the surface of a carrier substrate and electrically connected to carrier substrate via solder connections. FIG. 13A illustrates one embodiment. FIG. 13B illustrates one embodiment with end terminals.

FIG. 14 illustrates cross-sectional views of a wire-bond carrier substrate hosting first substrate and wire-bond connections. FIG. 14A illustrates a single substrate on wire-bond carrier substrate. FIG. 14B and FIG. 14C illustrate a plurality of substrates on wire-bond carrier substrate.

FIG. 15 illustrates a cross-sectional view of a substrate embedded inside a carrier substrate.

FIG. 16 illustrates cross-sectional views of a substrate comprising a network and additional packaging features, such as solder balls, through-substrate vias, and direct-bond contacts.

FIG. 17 illustrates a cross-sectional view of a substrate comprising a network comprising a resonator in a cavity.

FIG. 18 illustrates cross-sectional views of a substrate comprising a network comprising a resonator in a cavity electrically connected to a carrier substrate via solder connections and solder balls.

FIG. 19 illustrates a cross-sectional view of a substrate comprising a network comprising a resonator in a cavity and two load capacitors shunted between two ports of the resonator and a third port.

FIG. 20A illustrates a perspective view of a singulated substrate from a mother substrate and the re-oriented singulated substrate attached to carrier substrate. FIG. 20B-D illustrates several embodiments of the substrate with wire-bond contacts.

FIG. 21 illustrates several perspective views of substrates designed for a footprint-matching application for solder connection to a carrier substrate.

FIG. 22 illustrates several top views of a thin film trimmed by a plurality of ablation operations along a path. FIG. 22A-C illustrates an open path to the edge of thin-film feature. FIG. 22D illustrates a closed path internal to the thin-film feature.

FIG. 23 illustrates perspective views of an integral parallel plate capacitor. An untrimmed, open-path-trimmed, and closed-path-trimmed capacitor are illustrated.

FIG. 24 illustrates perspective views of an untrimmed and a trimmed capacitive device comprising a plurality of parallel-connected capacitive devices.

FIG. 25 illustrates several cross-sectional views of a substrate comprising an electrical interconnect between a plurality of capacitive device. The electrical interconnect is illustrated on or near the surface of the substrate, internal to the substrate and external to a resonator cavity, and internal to the resonator cavity in the substrate.

### DETAILED DESCRIPTION

One aspect of the present invention is a high-quality resonator structure that increases ease of use, lowers cost of manufacturing, and improves reliability, performance, low power dissipation, and miniaturization. In some aspects the apparatus includes a frequency reference containing a high quality factor resonator enclosed in a cavity in series with a capacitor. A further aspect includes a method of interfacing a feedback network to other elements of an apparatus.

Operation of embodiments of the present invention may be illustrated by example.

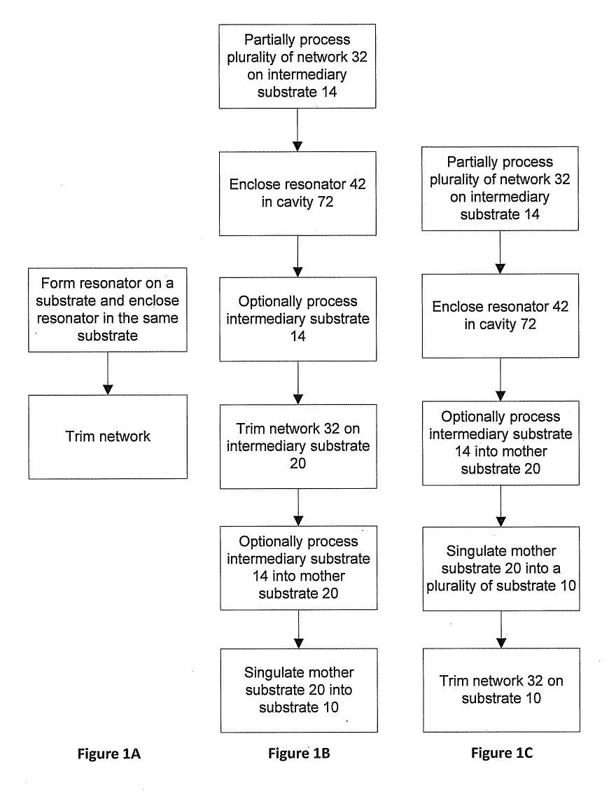

FIG. 1 depicts methods of manufacturing a structure containing a high quality factor resonator enclosed in a cavity, constructed and operative in accordance with an embodiment of the present invention. FIG. 1A flow charts a method of manufacturing, where a trimming operation on an electrical network is performed after a constituent resonator is enclosed in a substrate.

Substrate and some Elements

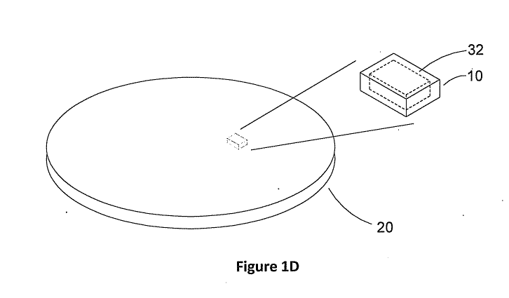

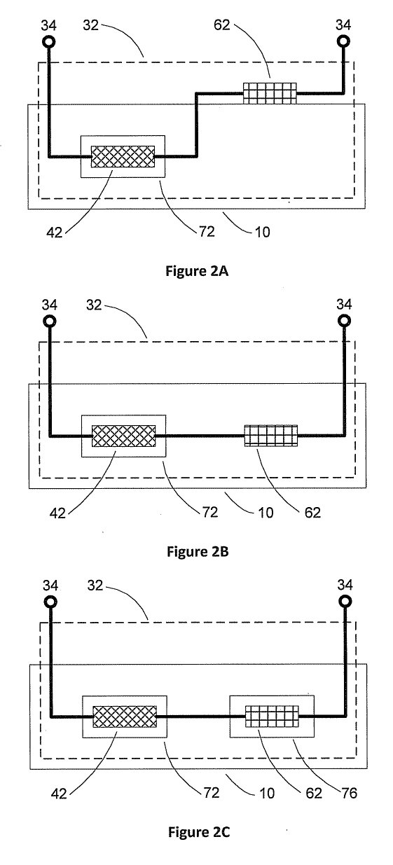

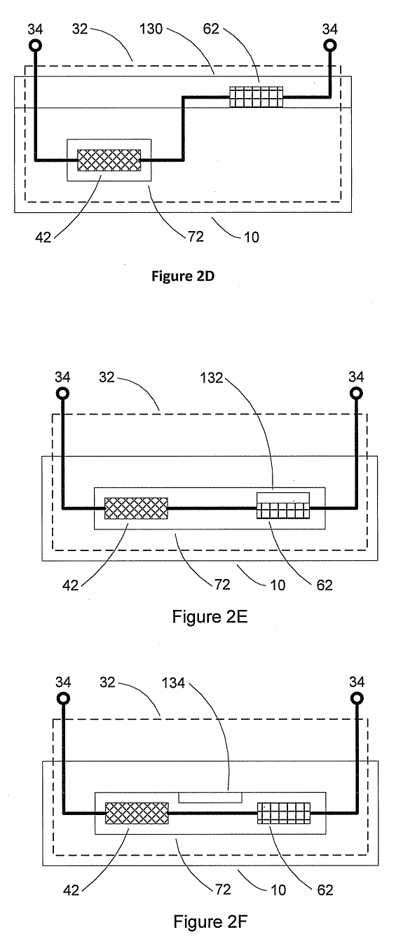

Turning to FIG. 2, FIG. 2 depicts an electrical network, constructed and operative in accordance with an embodiment of the present invention. In this embodiment, a substrate 10 comprises network 32, which includes a resonator 42 and a capacitive device 62. Resonator 42 is enclosed in cavity 72, and resonator 42 and capacitive device 62 are connected in series. Network 32 minimally comprises one port 34. Capacitive device 62 may be on or near the surface of substrate 10, as illustrated in FIG. 2A. Capacitive device 62 may be internal to the substrate 10, as illustrated in FIG. 2B. In another embodiment, capacitive device 62 is internal to substrate 10 and is enclosed in second cavity 76, as illustrated in FIG. 2C. In yet a further embodiment, capacitive device 62 may be on the surface of substrate 10, and film 130 includes protective and/or insulating material may be disposed above capacitive device 62, as illustrated in FIG. 2D. In yet a further embodiment, capacitive device 62 may be internal to cavity 72 and have material 132 disposed thereon, as illustrated in FIG. 2E. In yet a further embodiment, capacitive device 62 may be internal to cavity 72 and cavity includes film 134, as illustrated in FIG. 2F. It is understood by those familiar with the art that the thick solid orthogonal lines in all drawings of electrical network 32 represent an electrical connection rather than a physical feature. When a device is described to be on the surface of substrate 10, film 130 may be disposed above the device. That is, a device described to be on the surface of a substrate may be near the surface and have additional materials disposed thereon.

Micromechanical Network

A micromechanical network in accordance with the present invention comprises a mechanical or micromechanical device including but not limited to an acoustic resonator. A micromechanical network may also comprise an electrical device, including but not limited to a capacitive device, inductive device, resistor, and electrical network. Mechanical or micromechanical device may serve in an electrical capacity and electrical connection of additional electrical device to the mechanical or micromechanical device may form an electrical network.

Laser Trimming

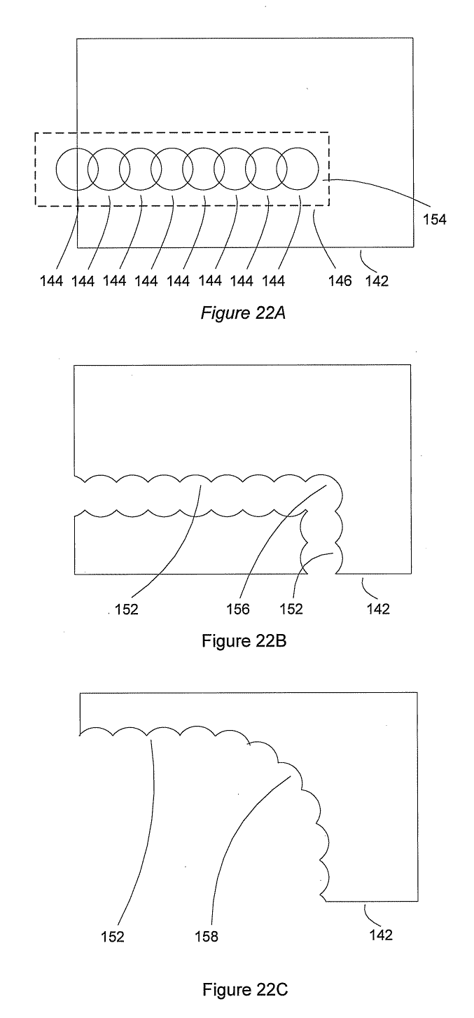

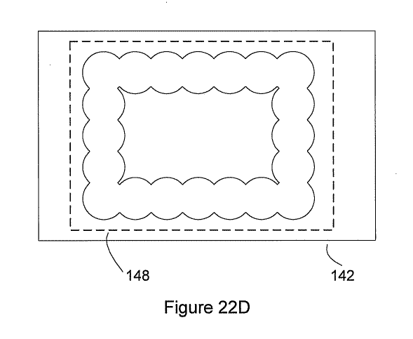

Laser trimming is beneficial in making precise and/or accurate modification to structures. Laser trimming is most beneficial for customization and/or reduction of manufacturing variations. However, by-products of the laser trimming operation may negatively impact operation of an apparatus. Since a laser heats and ablates select materials, debris is commonly scattered in surrounding areas. Selection of target material with high absorption to the laser wavelength and selection of surrounding materials with low absorption to the laser wavelength is critical. To minimize by-products and damage to surrounding regions, low-power pulsing of the laser to create a plurality of ablation operations along a trimming path 146 may be used, as illustrated in FIG. 22A. As the laser spot is circular with a Gaussian distribution, circular voids 144 are created in a trimmed thin film 142. A path end 154 may have a rounded profile. Thin film 142 may have an edge 152 with a profile resembling a series of connected arcs, as illustrated in FIG. 22B. Corner feature 156 may also be rounded. Because manufacturing repeatability at corner features may be challenging, path 146 may have a curved segment in place of a corner feature 156. Thin film 142 may have a curved edge 158, as illustrated in FIG. 22C. Repeatability of laser position on the substrate relative to features on the substrate is challenging. Therefore, the remaining area in a thin-film feature after trimming a closed internal path 148 (i.e. a closed path internal to the thin-film feature), as illustrated in FIG. 22D, is more accurate than the remaining area after trimming an open path, as illustrated in FIG. 22B and FIG. 22C. A laser may ablate materials above and below the target thin film. Therefore, a variety of undesirable results may occur in a laser trimming operation. Thus, enabling efficacious laser trimming is non-trivial.

Capacitor Trimming

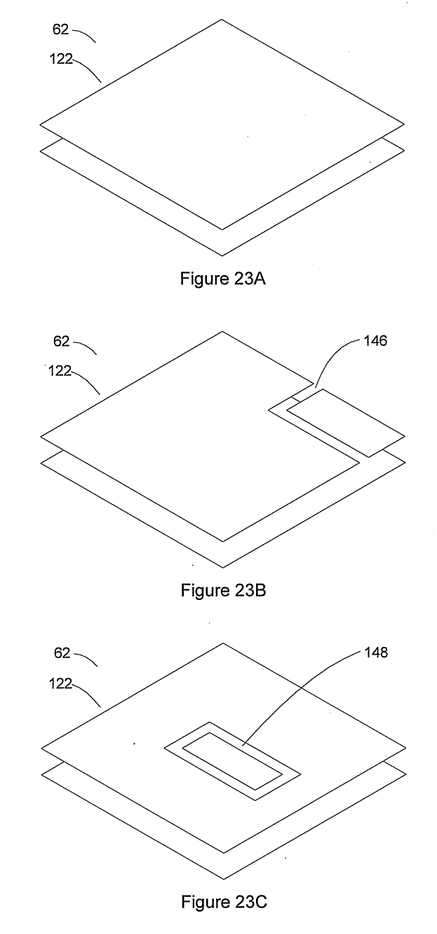

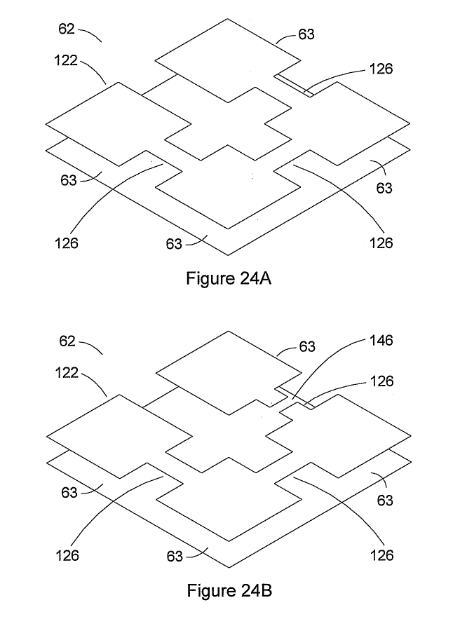

A fundamental feature in the first aspect of the present invention is enabling laser trimming of a capacitive device without negatively affecting the condition of a resonator in a cavity. Series capacitive device 62 may be trimmed by laser to modify the resonant frequency of network 32. Since a resonator in pristine condition and in a pristine cavity environment is desired for performance and reliability, it is desirable that by-products from the trimming operation of capacitive device 62 do not negatively impact the cavity environment. At the least two methods are possible for trimming capacitive device 62. First, consider one integral capacitive device 62, as illustrated in FIG. 23A. In one embodiment, the effective area or electrically-connected area of one electrode film 122 of capacitive device 62 may be reduced by trimming open path 146, thereby reducing the electrically-connected overlap area and reducing the capacitance of capacitive device 62, as illustrated in FIG. 23B. In another embodiment, the electrically-connected area of electrode film 122 may be reduced by trimming closed internal path 148, as illustrated in FIG. 23C. Second, consider capacitive device 62 comprising a plurality of parallel-connected capacitive device 63, as illustrated in FIG. 24A. An electrical interconnect 126 to one or more of the plurality of parallel-connected capacitive device 63 may be broken, thereby reducing the electrically-connected overlap area and reducing the capacitance of capacitive device 62, as illustrated in FIG. 24B. Reducing the area of electrode film 122 of capacitive device 62 or breaking the interconnect 126 to part of capacitive device 62 are two ways to trim capacitive device 62.

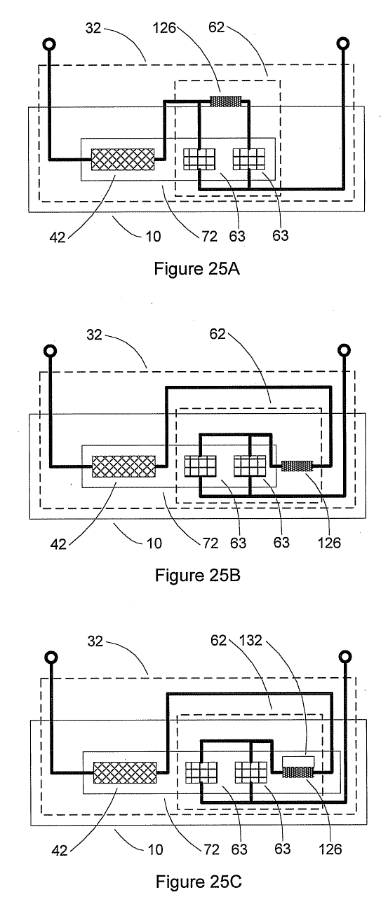

One method to maintain a pristine resonator 42 and pristine cavity environment while enabling trimming is to have the trimmed element external to cavity 72. In one embodiment, at the least half of capacitive device 62 is disposed external to cavity 72. In another embodiment, electrical interconnect 126 to portions of capacitive device 62 are external to cavity 72. Capacitive device 62 may be partially internal, wholly internal, or wholly external to cavity 72. Electrical interconnect 126 may be on or near the surface of substrate 10, as illustrated in FIG. 25A. Electrical interconnect 126 may be internal to substrate 10 and external to cavity 72, as illustrated in FIG. 25B. In the latter three described embodiments, substrate 10 comprises an electrically-conductive feature associated with accumulating the capacitance of capacitive device 62 external to cavity 72. In yet a further embodiment, electrical interconnect 126 may in internal to cavity 72 and have material 132 disposed thereon, as illustrated in FIG. 25C. The object of material 132 follows.

Returning to FIG. 2E, another method to maintain a pristine resonator 42 and pristine cavity environment while enabling trimming is to have a material to capture, absorb, and/or adsorb any by-products of the trimming operation from entering cavity 72. In one embodiment, capacitive device 62 is in cavity 72 and material 132 is disposed on capacitive device 62 to capture, absorb, and/or adsorb any by-products of the trimming operation, as illustrated in FIG. 2E. Material 132 is selected to have low absorption to the selected wavelength used for trimming thin film 142, electrode film 122, and/or interconnect 126. The wavelength of the laser may alternatively be selected to be benign to material 132.

In another embodiment, cavity 72 comprises capacitive device 62 and film 134 to getter any undesired gas and/or adsorb any undersired particles in cavity 72, as illustrated in FIG. 2F. Film 134 may be disposed on any surface of cavity 72.

In the case of trimming of a capacitive device connected in series to an asymmetric resonator, the pre-trim resonant frequency of the network is to be less than the desired resonant frequency because reducing the capacitance of the capacitive device causes an increase in the resonant frequency.

Method of Manufacturing

Returning to FIG. 1, the method of manufacturing is depicted in FIG. 1. Trimming of network 32 is performed after resonator 42 is enclosed in cavity 72. Trimming of network 32 may comprise trimming series capacitive device 62. In practice of manufacturing, mother substrate 20 comprises a plurality of substrate 10 each includes network 32, as illustrated in FIG. 1D. In one method of manufacturing, the majority of processing is completed (including enclosing resonator 42 in cavity 72), then network 32 is trimmed while it is a part of an intermediary substrate 14, as illustrated in FIG. 1B. Intermediary substrate 14 may be optionally processed after trim, such as cleaning, thinning, polishing, and/or solder bumping. Intermediary substrate 14 is considered a mother substrate 20 when it is ready for singulation. Singulation of mother substrate 20 yields a plurality of substrate 10. One benefit of this method of manufacturing is the extensive parallel processing of network 32 on intermediary substrate 14. Substrate-level processing, also known as wafer-level processing, is realized in this example.

In a second method of manufacturing, the majority of processing is completed (including enclosing resonator 42 in cavity 72), followed by singulation of mother substrate 20 into a plurality of substrate 10, and followed by trimming of network 32, as illustrated in FIG. 1C. The processing of substrate 10 is completed to a fuller extent than the former method before network 32 is trimmed. This method enables shorter lead time manufacturing of substrate 10 for custom load capacitances. Because lead times can be substantially reduced compared to quartz crystal units, inventories of custom and low-volume product can be reduced. Furthermore, inventories can be kept as generic work-in-progress rather than as customized product.

The described methods and the illustrations in FIG. 1A-C are merely subsets of processes in the complete method of manufacturing and do not preclude other processes and/or operations. It is understood that the two described methods of manufacturing (as illustrated in FIG. 1B and FIG. 1C) are not mutually exclusive. That is, more than one trim operation of network 32 may take place. Further, it is understood that material trimming and/or laser trimming of resonator 42 before and after enclosing resonator 42 in cavity 72 may be performed. The present invention does not preclude resonator trimming—It enables a critical trim operation of network 32 to be performed after resonator 42 is enclosed in cavity 72. While acoustic resonators are a suitable solution for frequency references, the described methods are applicable to any resonator, including but not limited to acoustic resonators, electromagnetic cavity resonators, and LC resonators.

Substrates

Substrates, especially those used in advanced manufacturing, commonly comprise semiconductor materials, piezoelectric materials, glass, ceramics, and other materials. Bonding more than one substrate of similar or differing materials produces a substrate that can then be processed as a single substrate. Furthermore, substrates are amenable to have materials deposited on their surface. For example, some regions of a substrate may be formed by chemical vapor deposition, physical vapor deposition, epitaxial growth, atomic layer deposition, electro-chemical plating, various farms thereby, and other additive processes. Substrates are also amenable to have materials removed from the bulk of the substrate or from the disposed films. The normal of a substrate is the direction perpendicular to the disposed films. The disposed films are commonly, parallel to the major surfaces.

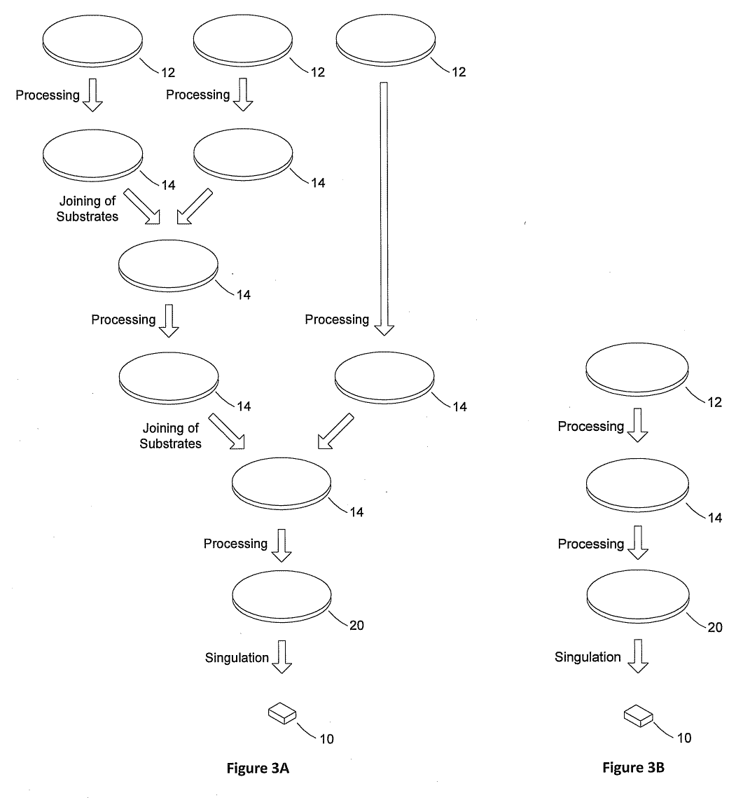

Substrate, initial substrate, intermediary substrate, and mother substrate are described. An initial substrate 12 is often planar and thin relative to its planar dimensions, as illustrated in FIG. 3, constructed and operative in accordance with an embodiment of the present invention. Initial substrate 12 may be circular, rectangular, or irregular shape in its planar geometry. Initial substrate 12 has no patterned features. (A bonded silicon-on-insulator substrate, albeit a physically-joined combination of initial substrates, is an initial substrate if it has no patterned features.) Any patterning of initial substrate 12 yields an intermediary substrate 14. Physically joining one or more patterned substrates with one or more initial substrate 12 and/or intermediary substrate 14 yields a newly-formed intermediary substrate 14. One embodiment utilizing three initial substrate 12 and two joining processes is illustrated in FIG. 3A. Complete processing of a substrate may be performed without joining of any two substrates, as illustrated in FIG. 3B. Intermediary substrate 14 remains intermediary through subsequent processing until it is ready for singulation, at which it is considered to be a mother substrate 20. A plurality of similar substrate 10 may be obtained by singulating mother substrate 20. The singulated substrate 10 are commonly rectangular and may have other geometries. Substrate 10 may have planar dimensions of the same order, and possibly even smaller, than the dimension along the normal of the disposed films.

The definition of substrate and assemblies precluded from being a substrate are discussed. Physically joining a plurality of substrates with similar lateral profile yields a newly-formed substrate. An assembly of substrates with dissimilar outer profiles is not a substrate.

In some instances, reduced thickness (i.e. the dimension along the normal of the films) of substrate 10 is beneficial. Initial substrates used in semiconductor processing have standard thicknesses for a particular diameter. For example, thicknesses for standard 150-mm, 200-mm, and 300-mm silicon substrates are 675 micrometers, 725 micrometers, and 775 micrometers, respectively. Substrates formed by bonding a plurality of substrates may exceed these thickness dimensions. For smart-card applications, the thickness of substrate 10 is desired to be less than 400 micrometers. For application in thin electronic packages and multi-chip packages, the thickness of substrate 10 is desirable to be less than 200 micrometers. Initial substrate 12, intermediary substrate 14 and/or mother substrate 20 may be thinned to reduce the thickness and achieve the desired thickness of substrate 10.

The cost of manufacturing is largely the raw material cost and total processing cost of mother substrate 20. For this reason, it may be beneficial to maximize the number of instances of substrate 10 on mother substrate 20. In another situation, it may be beneficial to reduce the total processing cost of mother substrate 20 to minimize the cost of substrate 10.

Temperature Stability

The temperature stability of a fixed-frequency oscillator is important. Various methods may be utilized to provide a stable oscillation frequency. In most cases, a temperature-stable feedback network is the solution.

Resonator & Process

Resonator 42 may be constructed using any known resonator technologies, including but not limited to quartz technology, surface acoustic wave (SAW) resonator technology, film BAW resonator technology, surface-micromachined capacitive resonator technology, bulk capacitive resonator technology, and any combination thereof. In one embodiment, resonator 42 comprises top conductive electrode film, piezoelectric material, bottom conductive electrode film, and compensating material. Top conductive film, piezoelectric material, and bottom conductive electrode film form the piezoelectric stack. Compensating material has a positive acoustic velocity temperature coefficient to compensate the commonly negative temperature coefficient of the acoustic velocity of most materials. Compensating material and piezoelectric stack may be engineered to form a resonator with a temperature-stable resonant frequency. Compensating material may be silicon dioxide. Piezoelectric material may be selected from the group including, but not limited to, quartz, aluminum nitride, zinc oxide, lead zirconium titanate (PZT), lithium niobate, lithium tantalite, langasite, and barium titanate. Piezoelectric material may be a part of an initial substrate (i.e. a bulk material) or a disposed film. Materials for conductive electrode films may be selected from the group of materials used in semiconductor, quartz resonator, SAW resonator, and film BAW resonator manufacturing.

In another embodiment, resonator 42 comprises top conductive electrode film, piezoelectric material, and bottom conductive electrode film. Piezoelectric material may be a particular cut of quartz with a desired temperature characteristic of its acoustic velocity. Compensating material is not necessary in an embodiment such as a quartz resonator that is self-compensated.

In another embodiment, resonator 42 comprises one conductive electrode film and piezoelectric material. Two electrodes may be patterned out of one electrode film, such as in a SAW resonator.

In another embodiment, resonator 42 comprises one conductive electrode film, piezoelectric material, and compensating material.

In another embodiment, resonator 42 comprises top conductive electrode film, piezoelectric material, bottom conductive electrode film, compensating material, and structural material such as single crystal silicon. Structural material provides the benefit of structural integrity and mode shape optimization.

Material 132 may comprise compensating film such as silicon dioxide, structural material such as single crystal silicon, and/or any disposed film. Furthermore, the materials on which capacitive device 62 is disposed upon may serve as material 132 to capture, absorb, and/or adsorb the by-products of the trimming operation.

Resonator 42 itself need not have a temperature-insensitive resonant frequency. Rather, the temperature stability of network 32 is important for a stable oscillation frequency.

Capacitive Devices

Capacitive devices are considered. As the present invention considers a fixed-frequency oscillator, stability of the capacitance of capacitive device 62 is important. Capacitive device 62 is a solid-dielectric fixed-capacitance device. A voltage-variable capacitance is unsuitable in the present invention. Voltage-variable capacitances are inherently not stable, as the voltage control is intended to provide a means of tuning. Furthermore, capacitors that may be affected by externalities are not suitable. For example, a free-space capacitor having a free-space gap (i.e., not a solid-dielectric capacitor) is less stable than a solid-dielectric capacitor because the gap may change due to substrate stress and/or vibrations. Therefore, a capacitive device being voltage-variable or having a free-space gap is not suitable to serve as capacitive device 62.

Capacitive devices, when connected in parallel, can be treated as a single capacitive device for electrical analysis. Capacitive device 62, although described as a single capacitive device, may comprise a plurality of capacitive device 63 located at various regions of substrate 10 and connected in parallel. It is understood that part of capacitive device 62 may be internal to cavity 72, internal to substrate 10, internal to second cavity 76, on the surface of substrate 10, or near the surface of substrate 10.

The configuration of series capacitive device 62 to maximize the quantity of substrate 10 in mother substrate 20 is considered. One solution is to minimize the planar dimensions of network 32. In one embodiment, series capacitive device 62 or a portion thereof is overlapping resonator 42 when viewed normal to resonator electrode film. Series capacitive device 62 and resonator 42 may be overlapping when a substantial portion of series capacitive device 62 is internal to substrate 10, in cavity 76, on one surface of substrate 10, or near one surface of substrate 10.

The configuration of series capacitive device 62 to minimize the processing cost of mother substrate 20 is considered. Minimizing the number of layers to form network 32 is one solution. In one embodiment, series capacitive device 62 is formed from one or more layers used to form resonator 42. In another embodiment, series capacitive device 62 is formed entirely from some or all the layers used to form resonator 42.

The dielectric of series capacitive device 62 is considered. The resonant frequency of network 32 is dependent on the ratio of the static capacitance of resonator 42 to the capacitance of series capacitive device 62. (The static capacitance of resonator 42 is the inherent capacitance between the electrodes.) Ensuring stability of the resonant frequency over temperature requires the ratio of the capacitances to be deterministic. The permittivity of dielectric materials varies with temperature. In one embodiment, utilizing the same dielectric material in resonator 42 and series capacitive device 62 (i.e., using the piezoelectric material as the dielectric in series capacitive device 62) is beneficial for this purpose. In another embodiment, the dielectric in series capacitive device 62 and in resonator 42 are dissimilar, to provide a desired temperature-dependent characteristic in the resonant frequency of network 32. For example, the resonant frequency of resonator 42 may have a temperature dependency. The capacitance of series capacitive device 62 may vary with temperature to beneficially improve the temperature dependency of the resonant frequency of network 32.

Large-capacitance series capacitive device 62 is considered. When the as-fabricated capacitance of series capacitive device 62 is made to be large relative to the static capacitance of resonator 42, the trimming range of the resonant frequency of network 32 is large. To minimize the planar dimensions of series capacitive device 62, a variety of options are available. In one embodiment, the dielectric in series capacitive device 62 is thinner than the piezoelectric material in resonator 42. In another embodiment, the dielectric in series capacitive device 62 is a high-permittivity material. In a further embodiment, series capacitive device 62 may have features extending in the direction normal to substrate 10 (i.e., a three-dimensional capacitive device).

Electrical Interconnect

As shown in FIG. 5, constructed and operative in accordance with an embodiment of the present invention, a via is generally a vertical electrical interconnect. In reference to a substrate, the vertical direction is in the direction normal to the majority deposited films. Via 106 includes not only purely vertical interconnects but also angled interconnects extending partially in the vertical direction, as illustrated in FIG. 5A. Via 106 may serve the purpose of, including but not limited to, (1) connecting a device internal to substrate 10 to a device on or near the surface of substrate 10, as illustrated in FIG. 5A, (2) connecting a device internal to substrate 10 to electrical contact 92 on or near the surface of substrate 10, as illustrated in FIG. 5B, (3) generally connecting a device internal to substrate 10 to another feature on or in substrate 10 at a different z-location, and (4) for routing inside, on the surface, or near the surface of substrate 10. Via 106 may be formed from metal thin-films or doped semiconducting thin-films. Via 106 may be electro-chemically plated on substrate 10. Via 106 may be a thin-film interconnect on the surface of a vertical or partially-vertical sidewall. Via 106 may also be a trench-refilled interconnect.

Cavity

The cavity 72 provides a desired operating environment for resonator 42. Cavity 72 may be irregular (i.e. it may not be symmetric and may be closer to one surface of substrate 10). What constitutes inside or internal to cavity 72 and external to cavity 72 is defined. Suppose cavity 72 resembles the shape of a hollow toroid. The void at the center of mass and/or center of geometry of the toroid is external to the toroid. The same applies for cavity 72. Cavity 72 may only exist on one major surface of resonator 42 (i.e., the opposite surface of resonator 42 may be solidly mounted).

Cavity 72 may be formed by a number of methods. Two examples include (1) physically joining one intermediary substrate 14 with a recessed region to another substrate, and (2) removing sacrificial materials internal to an intermediary substrate and subsequent disposing of material to seal the cavity. Recessed regions in intermediary substrate 14 may have vertical sidewalls or sloped sidewalls created by dry or wet etching.

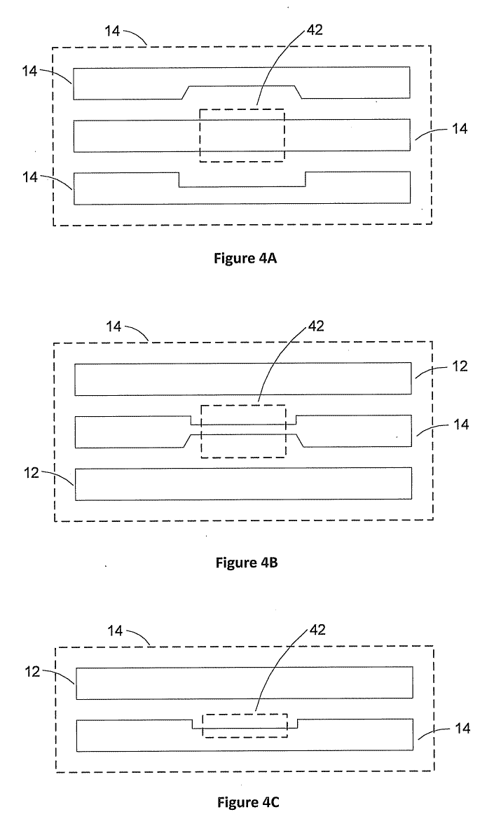

Moving to FIG. 4, constructed and operative in accordance with an embodiment of the present invention, an embodiment with recessed regions in a first and second intermediary substrate 14 and a resonator 42 in a third intermediary substrate 14 is illustrated as an exploded assembly in FIG. 4A. The resulting physically-joined three-substrate assembly will comprise cavity 72 enclosing resonator 42. The three-substrate assembly itself is an intermediary substrate 14. Another embodiment, with two recessed regions and a resonator 42 in an intermediate substrate 14 is illustrated in FIG. 4B. Cavity 72 may be formed by joining two initial substrate 12 to the intermediary substrate 14. In another embodiment, only two initial substrate 12 are necessary, as illustrated in FIG. 4C. Resonator 42 may be suspended in intermediate substrate 14 and/or cavity 72 may only be required on one surface of resonator 42. In a further embodiment, only one initial substrate is required to form mother substrate 20 and a plurality of similar substrate 10, as illustrated in FIG. 3B. Cavity 72 is formed by disposing of material on intermediary substrate 14. In the described embodiments, the use of any more than three initial substrate 12 is unnecessary.

Cavity 76 of series capacitive device 62 may be formed similarly to cavity. 72 of resonator 42. In the embodiment wherein series capacitive device 62 is enclosed in cavity 76, as illustrated in FIG. 2C, the separation between cavity 72 and cavity 76 may have low, moderate, or high permeability. The primary function of the separation is to inhibit by-products of laser-trimming series capacitive device 62 from contaminating cavity 72.

Additional Capacitors

Additional capacitive device may be formed on substrate 10 and included in network 32 to improve the performance, usability, and ease of manufacturing of network 32. Although the following modifications refer to network 32 described in above as the basic embodiment, it is understood that the modifications apply to all embodiments of network 32. Additional capacitive device may be added in series to elements in network 32 and in parallel to various branches of network 32 in a variety of arrangements. Additional capacitive device may be spatially disposed on or near the surface of substrate 10, internal to substrate 10, internal to cavity 72, or internal to cavity 76.

Additional series capacitive device is considered. More than one capacitive device in series can be modeled as a single equivalent capacitor. The equivalent capacitance of one or more capacitive devices in series is given by the following: the inverse of the equivalent capacitance is equal to the sum of the inverse of each capacitance in series. Trimming of, or change to, one series capacitive device has reduced effect on the equivalent capacitance, thus increasing trimming resolution. The increased resolution is most evident when a larger capacitance is trimmed. Trimming of the device with smaller capacitance provides the greatest range (i.e., course trim), and trimming of the device with larger capacitance provides the greatest resolution (i.e., fine trim).

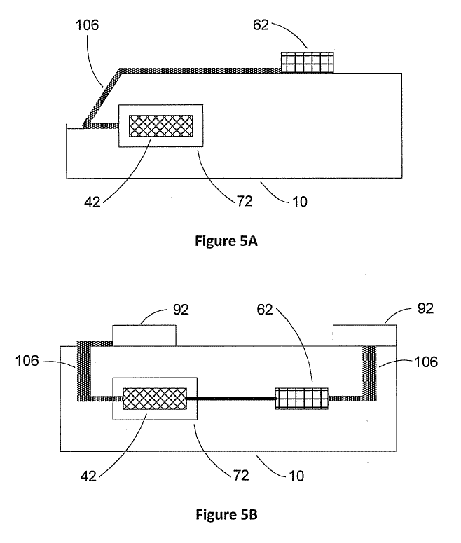

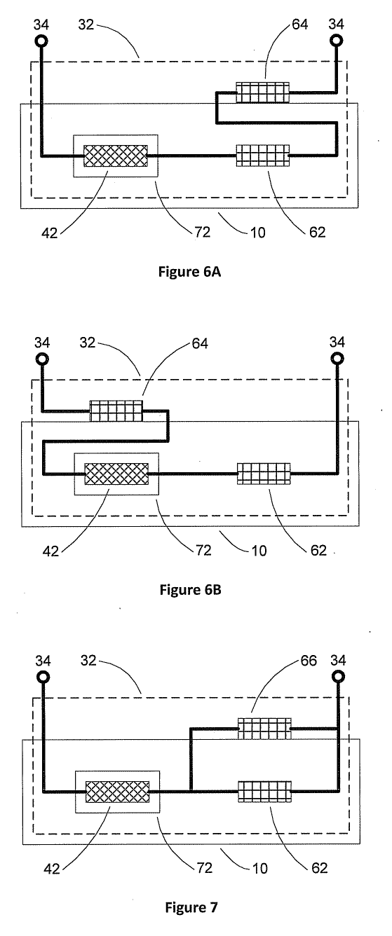

Several embodiments for adding a series capacitive device to network 32 are described. In one embodiment, series capacitive device 64 is added electrically between port 34 and series capacitive device 62, as illustrated in FIG. 6A, constructed and operative in accordance with an embodiment of the present invention. In another embodiment, series capacitive device 64 is added electrically between resonator 42 and first series capacitive device 62. In a further embodiment, second series capacitive device 64 is added electrically between port 34 and resonator 42 (i.e., at the port not connected to series capacitive device 62), as illustrated in FIG. 6B.

Additional capacitive devices to modify the total series capacitance are considered. In one embodiment, capacitive device 66 is added in parallel to series capacitive device 62, as illustrated in FIG. 7, constructed and operative in accordance with an embodiment of the present invention. By utilizing a dielectric material in capacitive device 66 dissimilar to the dielectric material in series capacitive device 62, the temperature dependency of the total series capacitance may be engineered. Capacitive device 66 may beneficially contribute in achieving a specific temperature dependency of the resonant frequency for network 32.

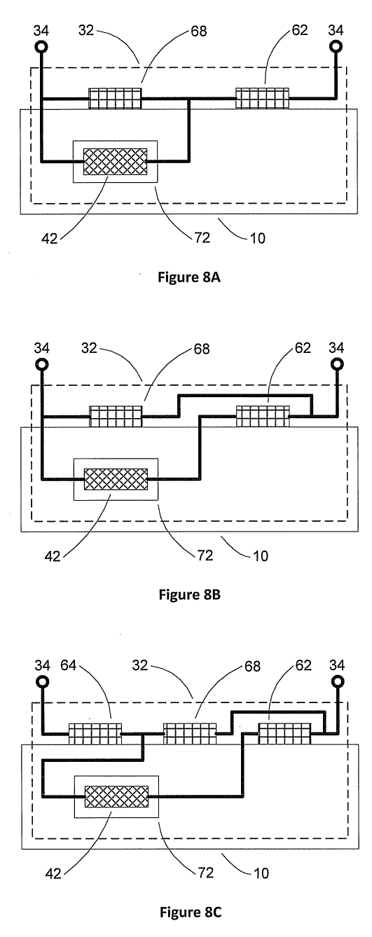

The inclusion of a capacitive device in parallel to other branches of network 32 may also be beneficial. One embodiment has capacitive device 68 in parallel to resonator 42, as illustrated in FIG. 8A, constructed and operative in accordance with an embodiment of the present invention. Capacitive device 68 reduces the tuning range of network 32 and reduces the sensitivity of the resonant frequency to the capacitance of capacitive device 62. Capacitive device 68, when placed in parallel to resonator 42, may be trimmed similarly to capacitive device 62 to tune the resonant frequency of network 32. The aspect of disposing a portion of capacitive device 68 external to cavity 72, disposing of interconnects to portions of capacitive device 68 external to cavity 72, or disposing of material 132 on capacitive device 68 is similar to the same aspect for capacitive device 62. Another embodiment has capacitive device 68 directly between ports 34 as illustrated in FIG. 8B, such that capacitive device 68 is in parallel to all other branches of network 32 between ports 34. The latter embodiment as illustrated in FIG. 8B has the advantage of enabling bi-directional trimming. For example, in network 32 includes an asymmetric resonator 42, trimming of series capacitive device 62 increases the resonant frequency of network 32, while trimming of parallel capacitive device 68 decreases the resonant frequency of network 32. A further embodiment has parallel capacitive device 68 in parallel to a branch includes resonator 42 and one of a plurality of series capacitive devices, as illustrated in FIG. 8C.

Load Capacitors

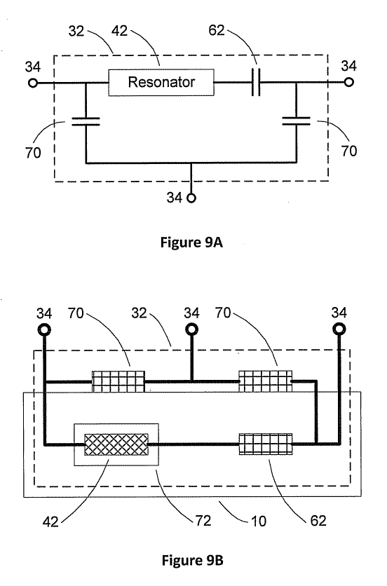

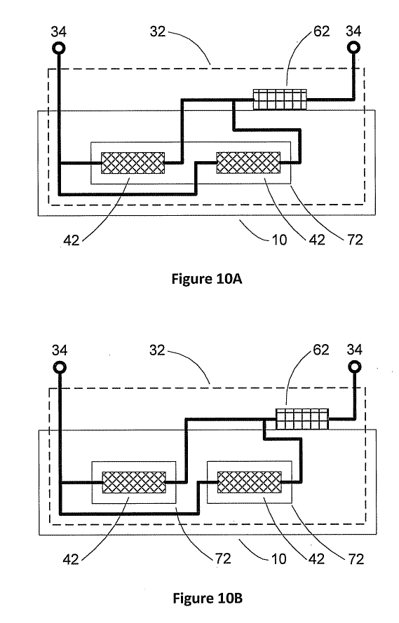

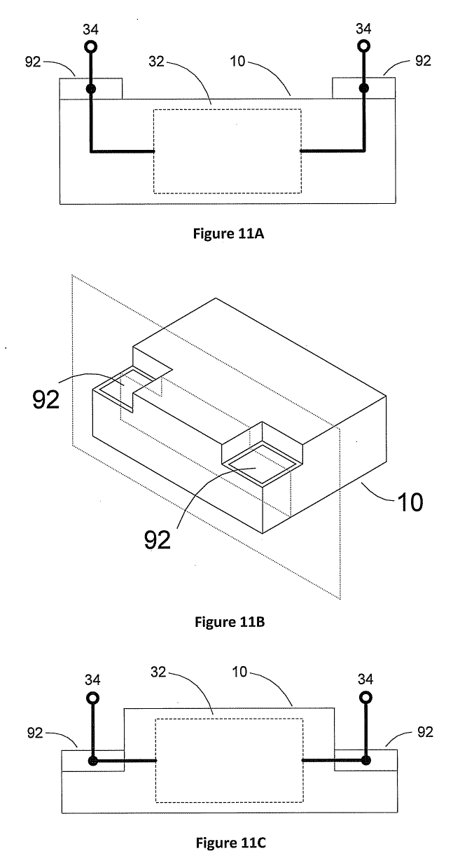

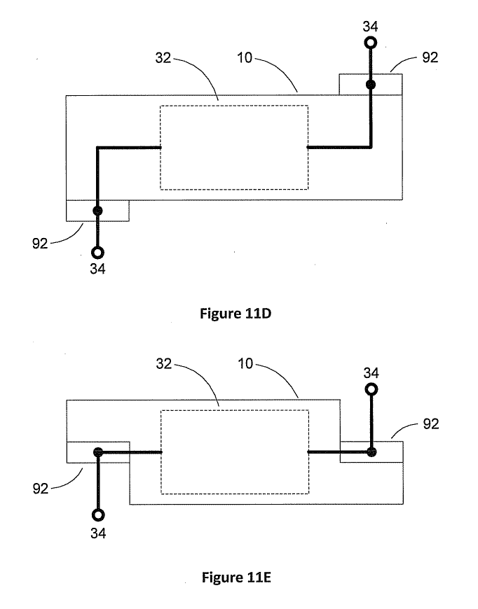

The inclusion of load capacitors in network 32 is considered. Load capacitors are often utilized in feedback networks. Forming load capacitors on substrate 10 is low-cost and will alleviate the need to form load capacitors elsewhere in the apparatus. In one embodiment, two load capacitors 70 are connected at two ports 34 and are shunted to a third port 34, as illustrated in FIG. 9A. In most cases, load capacitors 70 are shunted to a ground connection in an encompassing apparatus. In another embodiment, two load capacitors 70 are connected to the signal connection of two ports 34 and are shunted to the ground connection of two ports 34 (i.e., a port 34 may have both a signal and a ground connection).

Forming load capacitors 70 on substrate 10 is considered. In one embodiment, load capacitors 70 are disposed on or near the surface of substrate 10, while series capacitive device 62 is internal to substrate 10, as illustrated in FIG. 9B, constructed and operative in accordance with an embodiment of the present invention. In another embodiment, load capacitors 70 are disposed internal to substrate 10.

Additional Resonators

A plurality of resonators in substrate 10 may serve several benefits, although operation of network 32 in an oscillator application requires only one resonator. Redundancy in manufacturing network 32 may improve yield. In one embodiment, the plurality of resonators is designed to cover a range of frequencies near the desired resonant frequency. Since the frequency of the resonator may vary from manufacturing variations, a plurality improves the probability that one resonator has resonant behavior near the desired resonant frequency. The quality of each resonator may also differ A plurality improves the probability that at least one resonator has the preferred characteristics. After it is determined which resonator of the plurality is most suitable, the electrical connections between any other resonator and the network are to be broken. Methods to disconnect any undesired resonator to the network include but are not limited to laser link-processing and electrical fuse-processing. In one embodiment, the plurality of resonators is enclosed in cavity 72 as illustrated in FIG. 10A, constructed and operative in accordance with an embodiment of the present invention. In another embodiment, each resonator 42 is enclosed in a separate cavity 72 as illustrated in FIG. 10B. During operation of network 32, only one resonator of the plurality is necessary.

Differential-Mode Ports

Signal ports 34 may be single-ended or differential-mode. A differential-mode port requires two electrical contacts. An embodiment comprising two differential-mode ports therefore has four electrical contacts.

Signal ports 34 may be single-ended or differential-mode. A differential-mode port may comprise one signal connection and one ground connection. A differential-mode port may comprise two out-of-phase differential signal connections. A differential-mode port requires two electrical contacts. An embodiment consisting of two differential-mode ports therefore has four electrical contacts.

Open-Ended Ports and Electrical Contacts

An open-ended port or open-ended electrical contact on the substrate is to be connected to an off-substrate connection. The definition of “off-substrate” is “attributed to a different substrate”. In one embodiment, network 32 has at the least one open-ended port 34. In another embodiment, substrate 10 has at the least two open-ended electrical contact 92 on the substrate. The object in prior art is to integrate more devices into the same substrate, often driven by performance requirements and/or limitations (e.g., film BAW resonators with integrated electronics). Prior art substrate having network and IC do not have an open-ended port to prior art network. One major aspect of the present invention is to separate the manufacturing for beneficial economics while maintaining high performance.

A Plurality of Networks

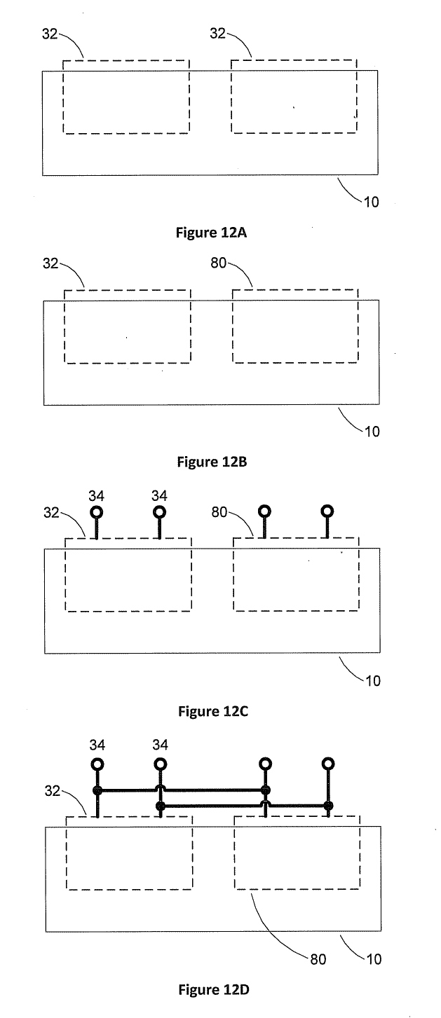

A plurality of network 32 may be formed on substrate 10, as illustrated in FIG. 12A. A plurality of network 32 sharing substrate 10 may be operating simultaneously. In one embodiment, the plurality of network 32 operates in a plurality of oscillator loops. The resonant frequency of the plurality may be distinct. That is, the plurality of oscillators may have different nominal oscillation frequencies.

Integrating other Devices

We now turn to FIG. 12, constructed and operative in accordance with an embodiment of the present invention. One or more additional devices 80 may be included on substrate 10 in addition to network 32, as illustrated in FIG. 12B. Device 80 may be a passive electrical device, active electrical network, optoelectronic device, optical device, electro-acoustic device, passive micromechanical device, active micromechanical device, micromechanical sensor, or microfluidic device. Furthermore, device 80 may be a resistor, network 32, matching network, low-pass filter, band-pass filter, high-pass filter, inductor, transformer, balun, large-capacitance capacitor, coupling capacitor, decoupling capacitor, tunable capacitor, diode, cooling device, switch, electrostatic discharge (ESD) protection device, electromagnetic interference (EMI) suppression device, integrated circuit for the oscillator, integrated circuit for a function other than an oscillator, energy harvesting device, inertial sensing device, microphone, pressure sensor, magnetic sensor, humidity sensor, optoelectronic emitter, photodiode, optical waveguide, optical grating, phononic crystal network, electrical pass-through interconnect, and electrical redistribution network. Device 80 may also be other devices that may be formed on a substrate. Forming network 32 and device 80 on substrate 10 may provide benefits in miniaturization, improve electrical performance, and reduced overall cost of manufacturing. Furthermore, network 32 and device 80 may have open-ended ports on substrate 10, as illustrated in FIG. 12C. Although FIG. 12C shows two open-ended ports for network 32, it is understood that network 32 may have one or more open-ended ports. Although FIG. 12C illustrates two open-ended ports for device 80, it is understood that device 80 may have one or more open-ended ports. Ports of device 80 may be single-ended or differential mode. Furthermore, device 80 may comprise an IC that together with network 32 forms an oscillator. Ports of network 32 may be connected to ports in device 80 (and are thereby not open-ended) as illustrated in FIG. 12D. However, any port of network 32 and device 80 may be connected to an off-substrate connection. Although forming network 32 together with a transistor network or “IC” on substrate 10 is possible, it is undesired for reasons described in the background. One object of the present invention is to obviate the need for having a common substrate for network 32 and a transistor network while maintaining desired performance.

Integrated Circuit, Active Electrical Devices, and Passive Electrical Devices

An IC in the context of this application, is an integrated circuit comprising a network of transistors. A transistor, network of transistors, transistor network, and integrated circuit are active electrical devices. Passive electrical devices include and are not limited to a resonator, resistor, capacitor, inductor, diode, passive switch, passive filter, electrical network comprising thereof, interconnect, via, electrical connections, and solder connections.

Network in Assemblies

In the aspect of packaging and assembly, the present invention greatly improves on prior art apparatus includes a frequency reference. There are a number of ways to physically connect substrate 10 and electrically connect network 32 in an apparatus. First, substrate 10 may be used as a bare-substrate discrete device that is soldered to a larger substrate (as in a chip resistor or chip capacitor), thus eliminating the cost of a metal, ceramic, or other types of package. Next, substrate 10 may be in a low-cost microelectronic package such as a plastic over-mold package. Also, it may share a microelectronic package with one or more integrated circuit substrates to enable functional integration and miniaturization. Additional methods to physically connect substrate 10 and electrically connect network 32 in an apparatus are possible. Substrate 10 may also comprise other features in addition to network 32.

Surface-Mount Network

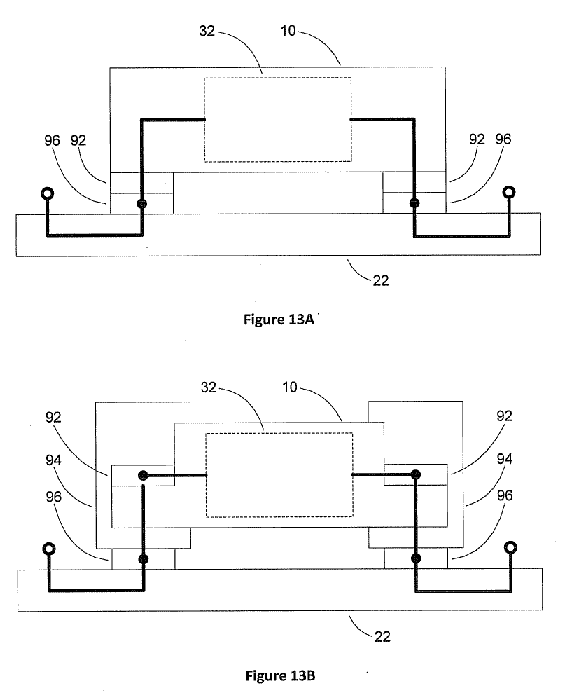

A plurality of solder connection 96 may be used for electrical connection of network 32 to a carrier substrate 22. Solder connection 96 enable substrate 10 to be surface-mounted on carrier substrate 22. Solder is a low-melting-point conductive alloy. Carrier substrate 22 may be a printed circuit board (e.g., formed from FR-4 and similar materials), a semiconductor substrate, a ceramic substrate, a glass substrate, a flexible substrate, or substrates formed from other materials. Turning to FIG. 13, constructed and operative in accordance with an embodiment of the present invention, in one embodiment, solder connection 96 provides an electrical connection between electrical contact 92 and carrier substrate 22, as illustrated in FIG. 13A. In another embodiment, solder connection 92 provide an electrical connection between terminals 94 formed on substrate 10 and carrier substrate 22, as illustrated in FIG. 13B. Terminals are common in chip resistor and chip capacitor substrates. Terminal 94 may serve multiple purposes, including but not limited to (1) acting as a conductive path between recessed electrical contacts 92 to a major surface of substrate 10, (2) providing an enlarged area for a solder connection to carrier substrate 22, and (3) providing an improved material interface to solder connection 96. Terminal 94 may be disposed on substrate 10 by plating, applying conductive paste and other methods. Compared to prior art, the resonant frequency of network 32, largely determined by the resonant frequency of resonator 42, does not require active correction for initial accuracy or temperature variation. Therefore, substrate 10 does not need to share a common package with an interface circuit and does not require wire-bond connections. Unlike ceramic resonators, substrate 10 and mother substrate 20 does not use LTCC technology and may be constructed using no more than 3 initial substrates. Ceramic resonator technology has inferior performance to quartz and thus is not suitable in most applications. This aspect of the present invention most improves on suitable prior art by obviating any metal package, ceramic package, plastic package, and wire bonds.

Wire-Bonded on a Carrier

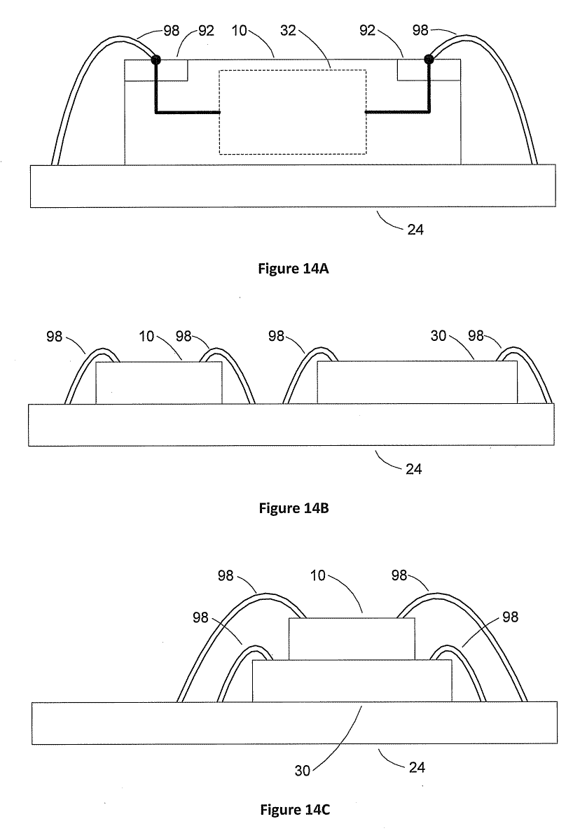

A plurality of wire-bond connection 98 may be used for electrical connection of network 32 to a wire-bond carrier substrate 24. A wire bond is commonly formed from aluminum alloys, gold, and copper wire. Wire-bond carrier substrate 24 may be a patterned conductive leadframe, commonly used in over-mold packaging or “plastic packaging” technology. Wire-bond carrier substrate 24 may also be a printed circuit board, a semiconductor substrate, an LTCC ceramic substrate, an HTCC ceramic substrate, or substrates formed from other common microelectronic packaging materials. A die attach material is commonly is used in between the device substrate and the carrier substrate. In one embodiment, substrate 10 is placed on wire-bond carrier substrate 24, and a plurality of wire-bond connection 98 are used to electrically connect electrical contacts 92 of network 32 to wire-bond carrier substrate, as illustrated in FIG. 14A, constructed and operative in accordance with an embodiment of the present invention. Substrate 10 may be the only substrate on wire-bond carrier substrate 24. In this aspect of the present invention, wire-bond carrier substrate 24 may serve the purpose of redistributing electrical contacts to a desired footprint. For example, it may be desirable for network 32 to have a footprint matching a larger quartz crystal. Wire-bond carrier substrate 24 may have two, three, or four contacts to match the footprint of a quartz crystal package.

Wire-Bonded on a Common Carrier, Juxtaposed

In another embodiment, wire-bond carrier substrate 24 may host substrate 10, second substrate 30, and a plurality of wire-bond connection 98, wherein substrate 10 and second substrate 30 are be juxtaposed, as illustrated in FIG. 14B. Wire-bond connection 98 may be formed between substrate 10 and wire-bond carrier substrate 24, and second substrate 30 and wire-bond carrier substrate 24. Wire-bond connection 98 may also be formed between substrate 10 and second substrate 30. Second substrate 30 may comprise an IC. Second substrate 30 may comprise an oscillator circuit to provide oscillator function together with network 32. Second substrate 30 may be larger or smaller than substrate 10. Wire-bond carrier substrate 24 may host more than two substrates.

Wire-Bonded on a Common Carrier, Stacked

In another embodiment, wire-bond carrier substrate 24 may host substrate 10, second substrate 30, and a plurality of wire-bond connection 98, wherein substrate 10 and second substrate 30 are vertically stacked. Die attach material may be disposed between substrate 10 and second substrate 30. Second substrate 30 may be between substrate 10 and wire-bond carrier substrate 24, as illustrated in FIG. 14C. Substrate 10 may be between second substrate 30 and wire-bond carrier substrate 24. Second substrate 30 may be larger or smaller than substrate 10. Wire-bond connection 98 may electrically connect wire-bond carrier substrate 24 to substrate 10 or second substrate 30, and substrate 10 to second substrate 30. Wire-bond carrier substrate 24 may host more than two substrates.

In another embodiment, wire-bond carrier substrate 24 may host substrate 10, more than one second substrate 30, and a plurality of wire-bond connection 98, wherein at the least two substrates out of the group of substrate 10 and the more than one second substrate 30 are vertically stacked.

Embedded in a Substrate

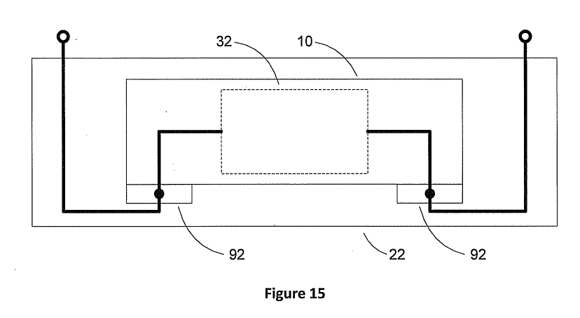

Substrate 10 may also be embedded in carrier substrate 22, as illustrated in FIG. 15, constructed and operative in accordance with an embodiment of the present invention.

Substrate Features—Routing and Interconnect

Substrate 10 may comprise a variety electrical routing and interconnect features. These features may be beneficial in microelectronic assemblies, including but not limited to three-dimensional packages (i.e., stacking of substrates in a microelectronic package) and chip-scale packages.

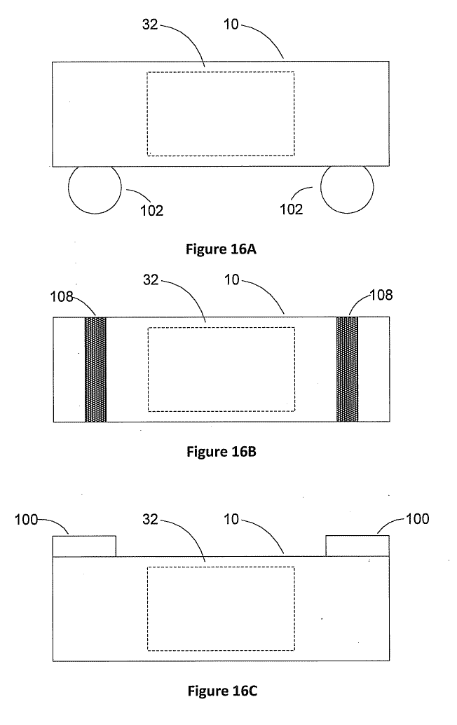

Solder balls are beneficial for connecting a substrate to a second substrate. In one embodiment, substrate 10 comprises network 32 and a plurality of solder ball 102, as illustrated in FIG. 16A, constructed and operative in accordance with an embodiment of the present invention. In another embodiment, substrate 10 comprises network 32, at the least one additional passive device 80, and a plurality of solder ball 102.

Through-substrate vias (TSV) enable signals on one surface of a substrate to be routed to a distal surface. In one embodiment, substrate 10 comprises network 32 and a plurality of TSV 108, as illustrated in FIG. 16B.

Redistribution network is beneficial for routing electrical signals to desired locations on a substrate. In one embodiment, substrate 10 comprises network 32 and redistribution network on at the least one of the major surfaces.

Direct-bond contacts on substrates are beneficial in many ways, including but not limited to serving as narrow-pitch interconnects between two substrates for high interconnect density. Also in contrast to solder which forms connections when heated, pairs of direct-bond contacts on two substrates are commonly mated by thermocompression bonding. Direct-bond contacts may be formed from materials including but not limited to copper and aluminum. In one embodiment, substrate 10 comprises network 32 and a plurality of direct-bond contact 100, as illustrated in FIG. 16C.

Pairs of interconnected electrical contacts on opposing surfaces of substrate 10 are beneficial in enabling a myriad of three-dimensional packaging solutions.

It is understood substrate 10 may comprise any combination of the described electrical routing and interconnect features.

Process-Compensated Resonator

A process-compensated design may be implemented for resonator 42 so that its resonant frequency is insensitive to processing variations. That is, the as-fabricated resonant frequency of resonator 42 may be within acceptable bounds. A plurality of resonator 42, methodically covering a narrow range of frequencies, on substrate 10 will further improve the probability that one resonator 42 will be within the acceptable bounds.

Embodiments without a Series Capacitive Device

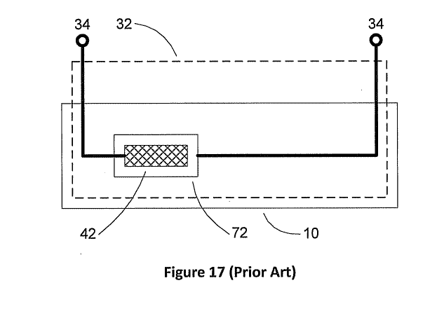

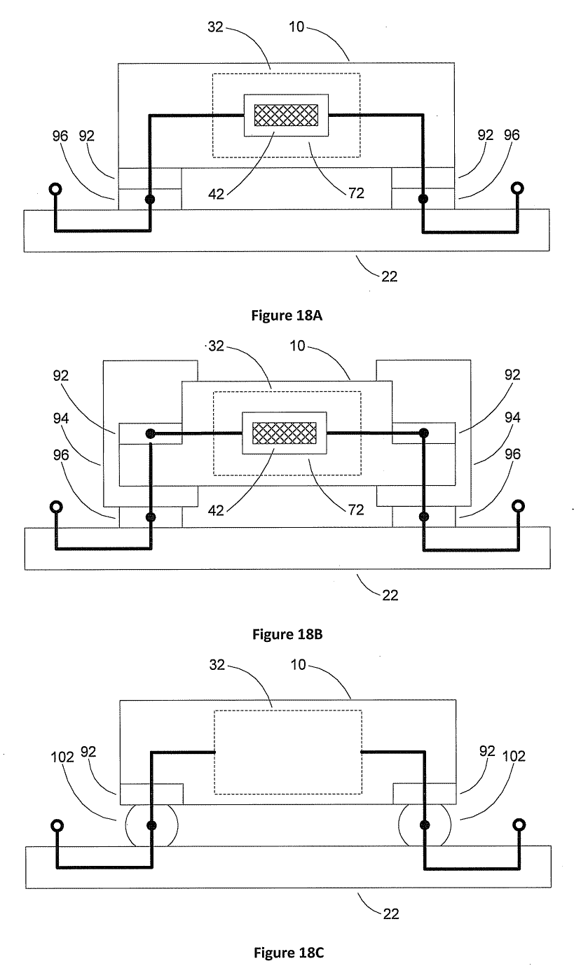

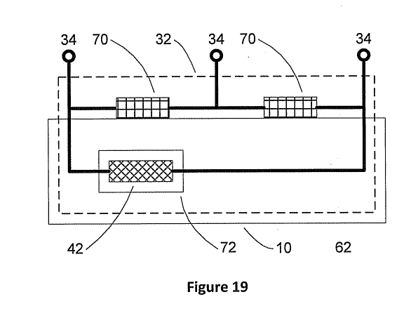

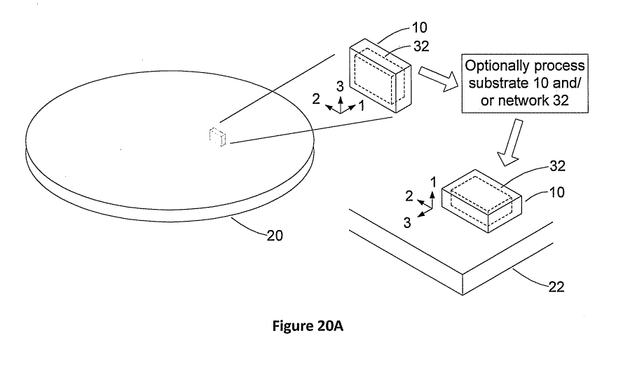

Network 32 only requires series capacitive device 62 if the as-fabricated resonant frequency of resonator 42 or any resonator out of a plurality is outside acceptable tolerances. In some cases, no additional series element in network 32 is necessary, as illustrated in FIG. 17, constructed and operative in accordance with an embodiment of the present invention. While a substrate that comprises a network includes a resonator encapsulated in a cavity is known to those skilled in the art, the prior art resonators required custom interface circuits and/or short wire bonds to ensure reliable operation. In the present invention, network 32 does not require custom interface circuits or wire bonds. While prior art ceramic resonator may be encapsulated in its substrate and attached to a carrier substrate via solder connections, it is formed with LTCC technology that has many limitations, including the greater thickness of the substrate, the poorer long-term stability of the resonator, and the inability to form some other devices on the substrate. Unlike prior art, network 32 formed on an improved non-LTCC substrate 10 may be electrically-connected directly to carrier substrate 22 through solder connections 96, as illustrated in FIG. 13A. In one embodiment of the present invention, substrate 10 comprises network 32 includes resonator 42 enclosed in cavity 72, wherein at the least two electrical contacts 92 are formed on substrate 10, and wherein network 32 is electrically connected to carrier substrate 22 via solder connections 96, as illustrated in FIG. 18A, constructed and operative in accordance with an embodiment of the present invention. In another embodiment, two end terminal 96 are formed on substrate 10 to facilitate the electrical connection to carrier substrate 22, as illustrated in FIG. 18B. In further embodiment, a plurality of solder ball 102 are formed on substrate 10 to facilitate the electrical connection to carrier substrate 22, as illustrated in FIG. 18C. In yet a further embodiment, a plurality of direct-bond contact 100 are formed on substrate 10 to facilitate the electrical connection to a second substrate with a plurality of direct-bond contact 100. In a further embodiment, substrate 10 may comprise network 32 includes resonator 42 enclosed in cavity 72 and load capacitor 70, as illustrated in FIG. 19, constructed and operative in accordance with an embodiment of the present invention. Furthermore, substrate 10 may comprise network 32 and one additional device 80 or a plurality of additional device 80.

Protective Film

A protective film may be disposed on substrate 10 to provide improved reliability. Protective film may be disposed on all surfaces or any select surface of substrate 10. Protective film may be patterned to enable electrical connection to substrate 10. Protective film may also be displaced by the application of force, such as during a wire-bonding process.

Networks per Mother Substrate (for a Wire-Bond Network.)

Maximizing the number of substrate 10 per mother substrate 20 (commonly referred to as gross die per wafer or DPW), is important in lowering the cost per substrate 10 and cost per network 32.

In some applications, it may be beneficial that substrate 10 be thin for thickness-constrained applications. For example, thickness or “z-height” of 0.4 mm or less may be required in low-profile assemblies. Furthermore, thickness or “z-height” of 0.2 mm or less may be beneficial for the same reason. In one application, it may be beneficial to have a large and thin substrate in a wire-bonded package.

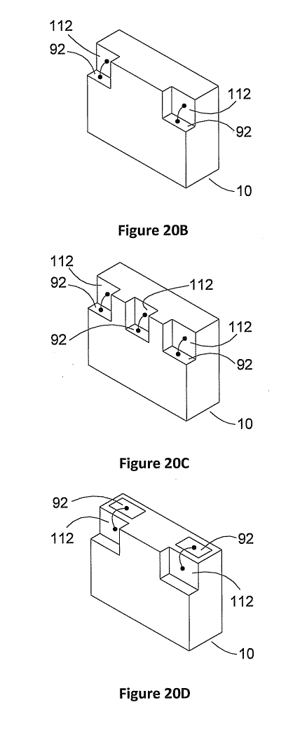

The following aspect of the present invention maximizes large DPW and reduces z-height. The z-height of substrate 10 does not need to be the z-height of mother substrate 20. Substrate 10 can be obtained from a re-oriented singulated portion of mother substrate 20 as illustrated in FIG. 20A, constructed and operative in accordance with an embodiment of the present invention. There are a number of benefits to a re-oriented substrate 10. First, a lateral dimension on mother substrate 20 becomes the z-height of substrate 10. More substrate 10 can be obtained from mother substrate 20 when the z-height of substrate 10 is reduced. Second, mother substrate 20 does not need to be thinned to the same extent.

In one embodiment, substrate 10 includes recessed electrical contact 92 is to be re-oriented onto carrier substrate 22 for a wire-bond application, wherein substrate 10 also comprises wire-bond contact 112. Wire-bond contact 112 is a conductive region on the sidewall of the recess. Electrical contact 92 may be electrically connected to a wire-bond contact 112, as illustrated in FIG. 20B and FIG. 20C. After re-orienting substrate 10, the wire-bond contact 112 must be considerably flat and planar. Said profile may be achieved by wet etch and/or dry plasma etch. Wire-bond contact 112 may be disposed and connected to electrical contact 92 by conformal conductive thin-film (e.g. metal) disposition. In another embodiment, electrical contact 92 is not recessed, and a recess is created for wire-bond contact 112, as illustrated in FIG. 20D. Wire-bond contact 112 may be similarly disposed and connected to electrical contact 92.

Networks per Mother Substrate (for a Matched-Footprint SMD Network)

In another application, it is beneficial for substrate 10 to have similar in-plane dimensions and electrical contact footprint as a quartz crystal (wherein the electrical contacts are commonly at the distal ends of the largest lateral dimension). Such an attribute enables substrate 10 to be attached to a carrier substrate 22 that was designed for a quartz crystal.

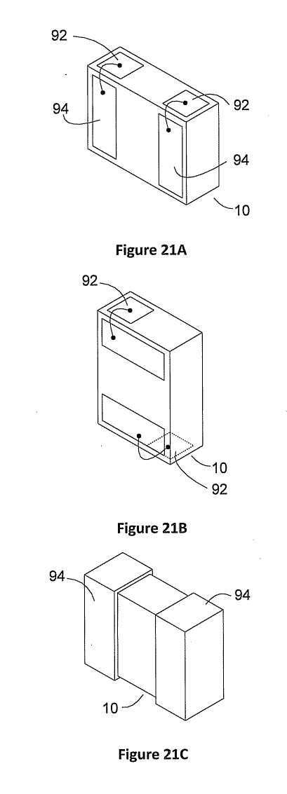

A first embodiment for maximizing DPW in a footprint-matching application is considered. For example, suppose the thickness of mother substrate 20 is 1.2 mm and the desired in-plane dimensions for substrate 10 is 1.0 mm by 0.8 mm. Further, suppose the desired z-height of substrate 10 is 0.4 mm. Mother substrate 20 is to be thinned to approximately 0.8 mm and to be singulated into segments with lateral dimensions of approximately 1.0 mm by 0.4 mm. The desired footprint of terminal 94 to be connected to electrical contacts 92 is illustrated in FIG. 21A, constructed and operative in accordance with an embodiment of the present invention.

A second embodiment for maximizing DPW in a footprint-matching application is considered. A greater quantity of substrate 10 may be obtained from mother substrate 20 than the first embodiment. The dimensions from the previous example are used in the following example. Mother substrate 20 is to be thinned to approximately 1.0 mm and to be singulated into segments with lateral dimensions of approximately 0.8 mm by 0.4 mm. For this embodiment, each of the two electrical contacts 92 need to be formed on opposing major surfaces of mother substrate 20 to connect to the desired footprint of terminal 94, as illustrated in FIG. 21B.

Terminal 94 may be disposed only on a desired surface of substrate 10, be disposed over the entire end of substrate 10 as illustrated in FIG. 21C, or be disposed on a portion thereof. Terminal 94 may connect to electrical contact 92 on or near the surface of substrate 10, or a recessed electrical contact 92.

A plurality of terminal 94 may be disposed at the four corners on one surface of a rectangular substrate 10. The plurality may be disposed to match a footprint of a quartz crystal package.

The dimensions referenced in the footprint-matching and z-height-targeted embodiments only represent one possible set of desired dimensions. It is understood that many sets of desired dimensions may be obtained utilizing the same principles in these embodiments of the present invention.

Combinations

Combinations and permutations of all described aspects are inhered in the present invention. Described aspects include and are not limited to the arrangement of substrate 10 in the apparatus, electrical connection of network 32 in the apparatus, additional devices on substrate 10, various forms of network 32, various physical arrangements of the elements in network 32 and various embodiments of the elements in network 32.

The previous description of the embodiments is provided to enable any person skilled in the art to practice the invention. The various modifications to these embodiments will be readily apparent to those skilled in the art, and the generic principles defined herein may be applied to other embodiments without the use of inventive faculty. Thus, the present invention is not intended to be limited to the embodiments shown herein, but is to be accorded the widest scope consistent with the principles and novel features disclosed herein.

What is claimed is:

1. An apparatus comprising:
an electrical oscillator further comprising a substrate with a resonator cavity;
an electrical network further comprising:
a resonator formed on the substrate, the resonator enclosed within the resonator cavity; and
a capacitive device formed on the same substrate, the capacitive device being connected in series with the resonator the capacitive device operates as a capacitive device and not as a resonator or inductive device; and
the substrate comprises an electrically-conductive feature associated with accumulating
the capacitance of the capacitive device disposed external to the resonator cavity, and
the substrate comprises at least two open-ended electrical contacts for an off-substrate electrical connection.

2. The apparatus according to claim 1,
wherein the capacitive device is a solid-dielectric fixed-capacitance device.

3. The apparatus according to claim 1,
wherein the electrical devices on the substrate are all passive.

4. The apparatus according to claim 1, the substrate further comprising:
at the least one electrical interconnect extending at the least five micrometers in a direction normal to a majority of one or more disposed electrode film of the resonator.

5. The apparatus according to claim 1,
wherein the capacitive device and the resonator are overlapping when viewed in a direction normal to a majority of one or more disposed electrode film of the resonator.

6. The apparatus according to claim 1,
wherein more than half the capacitance of the capacitive device is disposed external to the resonator cavity.

7. The apparatus according to claim 1,
wherein the substrate includes at least one device selected from the group of through-substrate via, redistribution network, solder ball, and direct-bond contact.

8. The apparatus according to claim 1,
wherein the apparatus includes a second substrate; and
wherein the electrical connections between the first and the second substrate are made through solder.

9. The apparatus according to claim 1,
wherein the substrate is enclosed in a surface-mount microelectronic package having no more than 4 electrical contacts.

10. An apparatus includes:
a substrate comprising one or more materials selected from the group including silicon, glass, quartz, lithium niobate, lithium tantalate, sapphire, other common semiconductor materials, and other common piezoelectric materials;
the substrate including a network, the network further comprising:
a resonator enclosed in a cavity, and
a carrier substrate, electrically connected to the network via solder connections.

11. The apparatus according to claim 10, wherein the substrate is constructed from no more than three initial substrates.

12. The apparatus according to claim 10, wherein the network is trimmed after the resonator is enclosed in the cavity.

13. The apparatus according to claim 10,
wherein a first substrate is re-oriented on the carrier substrate, such that a normal of a majority of disposed films is orthogonal to the normal of the carrier substrate.

14. The apparatus according to claim 14,
wherein the first substrate includes two open-ended electrical contacts for off-substrate electrical connection to the network.

15. The apparatus according to claim 10,
wherein the first substrate comprises a capacitive device connected in series to the resonator.

16. The apparatus according to claim 15,
an electrically-conductive feature associated with accumulating the capacitance of the capacitive device is disposed external to the resonator cavity.

17. An apparatus comprising:
a substrate with a resonator cavity;
an electrical network further comprising:
a resonator formed on the substrate, the resonator enclosed within the resonator cavity; and
a capacitive device formed on the same substrate, the capacitive device being connected in series with the resonator, and the capacitive device comprising a conductive film and a solid-dielectric film; and
the conductive film having high absorption to a select laser wavelength, and the conductive film having a disposed material thereon having low absorption to the select laser wavelength to capture, adsorb, and/or absorb any by-products of a plurality of ablation operations; and
the solid-dielectric film being altered by the plurality of ablation operations

18. The apparatus according to claim 18,
wherein the conductive film has an edge profile resembling a series of connected arcs

19. The apparatus according to claim 18,
wherein the conductive film comprises an internal closed-path electrically-disconnected region created by the plurality of ablation operations

20. The apparatus according to claim 18,
wherein an electrically-conductive feature associated with accumulating the capacitance of the capacitive device is disposed external to the resonator cavity
